(19) United States
(12) Patent Application Publication
(10) Pub. No.: US 2006/0022255 A1
(43) Pub. Date: Feb. 2, 2006

(54) Multi-oxide OTP device

(75) Inventors: Zeqiang Yao, Shanghai (CN); Xiangming Xu, Shanghai (CN)

Correspondence Address: BIRCH STEWART KOLASCH & BIRCH, PO BOX 747, FALLS CHURCH, VA, 22040-0747, US

(73) Assignee: Shanghai Hua Hong NEC Electronics Company Limited, Shanghai (CN)

(21) Appl. No.: 11/192,269

(22) Filed: Jul. 29, 2005

(30) Foreign Application Priority Data
Jul. 29, 2004 (CN) 200410053295.5

(51) Int. Cl. H01L 29/788

(52) U.S. Cl. 257/315

(57) ABSTRACT

A Multi-Oxide OTP (one time programmable) device is provided having different thicknesses of the gate oxide region at the transistor side and at the capacitor side, respectively, to increase the coupling efficiency of the capacitive transistor therein and improve the OTP programming rate. The present invention can be applicable to semiconductor integrated circuits and discrete components. More particularly, to single-poly EEPROM device.

### CROSS-REFERENCE TO RELATED APPLICATIONS

The present application claims priority under 35 USC 119 to Chinese Patent Application No. 200410053295.5 filed on Jul. 29, 2004 the entire contents of which are hereby incorporated by reference.

### BACKGROUND OF THE INVENTION

1. Field of the Invention

The present invention relates to a semiconductor integrated circuit device. More specifically, to structures involving a Multi-Oxide OTP (one time programmable) Device.

2. Description of the Related Art

In the development of a single-poly OTP device, the most important design consideration relates to how to increase coupling efficiency of the capacitive transistor, so as to improve the OTP programming efficiency.

Prior designs of a single-poly OTP device provided equal thicknesses for the oxidation layers which were employed at each side of a transistor and a capacitor thereof. Thereby, some extra driver circuits or special cells had to be inserted for increasing coupling efficiency.

Examples of early devices are described in the following articles:

Katsuhiko Ohsaki et. al, “A Single Poly EEPROM Cell Structure for Use in Standard CMOS Processes” IEEE JOURNAL OF SOLID-STATE CIRCUITS, VOL. 29, NO. 3, March, 1994.

David H. K. Hoe et. al, “Cell and Circuit Design for Single-Poly EPROM” IEEE Journal of Solid State Circuits, vol. 24, No. 4, August, 1989.

These articles reveal that if the coupling parameter P is too low, the programming rate and read current are degraded. Therefore, special driver circuitry or other devices are required to increase the coupling efficiency and consequently expanded the cell size.

### SUMMARY OF THE INVENTION

The primary object of the present invention is by increasing coupling efficiency of the capacitive transistor in a Multi-Oxide OTP Device to prevent unwanted expanding of cell size and for improving the programmable capability.

In accordance with the primary object of the present invention, an improved structure of a Multi-Oxide OTP Device is provided, wherein different thicknesses of a gate oxide film are formed at each side of the transistor and the capacitor thereof respectively. The thick gate oxide region is formed at the side of the transistor, and the thin gate oxide region is formed at the side of capacitor. Thereby, the coupling efficiency of the capacitive transistor is increased and the programming capability of the device is improved. Furthermore, the size of the chip is greatly reduced. The structure of the present invention can also be applicable to semiconductor integrated circuits and discrete components. More particularly to a single-poly EEPROM device.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a schematic drawing of present invention illustrating the structure of an improved Multi-Oxide OTP Device.

### DETAILED DESCRIPTION OF THE PREFERRED EMBODIMENTS

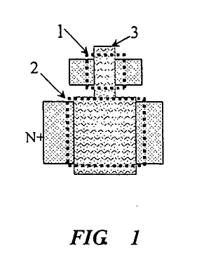

FIG. 1 shows the structure of the present invention device wherein at least a thick gate oxide region 1 is provided together with a thin gate oxide region 2 and a polysilicon 3.

It is a primary object of the present invention, to provide an improved Multi-Oxide OTP Device for increasing coupling efficiency which will be described in conjunction with the structure of the device illustrated in FIG. 1. In the embodiment of the device according to the invention, FIG. 1 shows different thicknesses of gate oxide film that are formed at each side of the transistor and the capacitor respectively. The thick gate oxide region 1 is formed at the side of the transistor. The thin gate oxide region 2 is formed at the side of capacitor.

The device of the present invention can be fabricated easily following a conventional integrated circuits process of Multi-Oxide CMOS. However, it should be realized that the implementation example is only the individual case concerning the implementation of this invention. Based on this implementation example, one skilled in the art can learn how this invention can be applied to other cases, e.g. in single-poly EEPROM.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A multi-oxide OTP, one time programmable device, comprising:
at least a thick gate oxide region;
a thin gate oxide region; and
a polysilicon;
wherein different thicknesses of gate oxide film are formed at the transistor side and the capacitor side respectively and wherein said thick gate oxide region is formed at the transistor side, and said thin gate oxide region is formed at the capacitor side.

2. The multi-oxide OTP, one time programmable device, according to claim 1, wherein the multi-oxide OTP device increases coupling efficiency of the capacitive transistor is increased.

3. The multi-oxide OTP, one time programmable device, according to claim 1, wherein the programming capability of the device is improved.

4. The multi-oxide OTP, one time programmable device according to claim 1, wherein the size of a chip forming the device is greatly reduced.

5. The multi-oxide OTP, one time programmable device according to claim 1, wherein the device is a single-poly EEPROM.

6. The multi-oxide OTP, one time programmable device according to claim 1, wherein the device is made with a process of a multi-oxide CMOS.

7. A multi-oxide OTP, one time programmable device, comprising:
a thick gate oxide region formed at a transistor side;
a thin gate oxide region formed at a capacitor side; and
a polysilicon;
wherein different thicknesses of gate oxide film are formed at the transistor side and the capacitor side, respectively.

8. The multi-oxide OTP, one time programmable device, according to claim 7, wherein the multi-oxide OTP device increases coupling efficiency of the capacitive transistor is increased.

9. The multi-oxide OTP, one time programmable device, according to claim 7, wherein the programming capability of the device is improved.

10. The multi-oxide OTP, one time programmable device according to claim 7, wherein the size of a chip forming the device is greatly reduced.

11. The multi-oxide OTP, one time programmable device according to claim 7, wherein the device is a single-poly EEPROM.

12. The multi-oxide OTP, one time programmable device according to claim 7, wherein the device is made with a process of a multi-oxide CMOS.
